(19) United States
(12) Patent Application Publication
(10) Pub. No.: US 2012/0146111 A1
(43) Pub. Date: Jun. 14, 2012

(54) CHIP PACKAGE AND MANUFACTURING METHOD THEREOF

(76) Inventors: Shu-Ming CHANG, New Taipei City (TW); Yen-Shih HO, Kaohsiung City (TW); Ho-Yin YIU, KLN (HK)

(21) Appl. No.: 13/324,815

(22) Filed: Dec. 13, 2011

Related U.S. Application Data
(60) Provisional application No. 61/423,036, filed on Dec. 14, 2010.

(51) Int. Cl. H01L 29/78; H01L 21/336

(52) U.S. Cl. 257/288; 438/197; 257/E29.255; 257/E21.409

(57) ABSTRACT

An embodiment of the invention provides a chip package including a semiconductor substrate, a drain electrode, a source electrode and a gate electrode. The semiconductor substrate has a first surface and an opposite second surface wherein the second surface has a recess. The drain electrode is disposed on the first surface and covers the recess. The source electrode is disposed on the second surface in a position corresponding to the drain electrode covering the recess. The gate electrode is disposed on the second surface. An embodiment of the invention further provides a manufacturing method of a chip package.

### CROSS REFERENCE TO RELATED APPLICATIONS

This Application claims the benefit of U.S. Provisional Application No. 61/423,036, filed on Dec. 14, 2010, the entirety of which is incorporated by reference herein.

### BACKGROUND OF THE INVENTION

1. Field of the Invention

The present invention relates to packaging technology, and in particular relates to a chip package and a manufacturing method thereof.

2. Description of the Related Art

A chip packaging process is an important step during the formation of electric devices. The chip package protects a chip from environmental pollution and provides electrical connections between electronic elements in the chip and electronic elements outside of the chip.

Performance improvement of chip packages and structural strength maintenance thereof, have become important issues.

### BRIEF SUMMARY OF THE INVENTION

An embodiment of the invention provides a chip package, comprising: a semiconductor substrate having a first surface and a second surface opposite thereto, wherein the first surface has a recess; a drain electrode disposed on the first surface and covering the recess; a source electrode disposed on the second surface in a position corresponding to the drain electrode covering the recess; and a gate electrode disposed on the second surface.

An embodiment of the invention provides a chip package, comprising: a semiconductor substrate having a first surface and a second surface opposite thereto, and having at least one recess extending from the first surface to the second surface, wherein the recess has a bottom; a drain electrode disposed on the first surface and covering the recess; a source electrode disposed on the second surface in a position corresponding to the drain electrode covering the recess; a gate electrode disposed on the second surface; a conductive feature electrically connecting the gate electrode, penetrating through the semiconductor substrate, and extending onto the first surface; an insulating layer disposed on the second surface and covering the gate electrode, wherein the insulating layer has an opening exposing the source electrode; and a conductive layer disposed on the insulating layer and connecting the source electrode through the opening.

An embodiment of the invention provides a method for forming a chip package, comprising: providing a semiconductor substrate, a source electrode and a gate electrode, wherein the semiconductor substrate has a first surface and a second surface opposite thereto, and the source electrode and the gate electrode are located on the second surface; forming a first recess on the first surface, wherein the first recess is in a position corresponding to the source electrode; and forming a drain electrode on the first surface, covering the first recess.

### BRIEF DESCRIPTION OF THE DRAWINGS

The present invention can be more fully understood by reading the subsequent detailed description and examples with references made to the accompanying drawings, wherein:

FIG. 1 is a cross-sectional view of a chip package according to an embodiment of the present invention;

FIGS. 2A-2D are top views of variations of recesses of chip packages according to embodiments of the present invention;

FIG. 3 is a cross-sectional view of a chip package according to an embodiment of the present invention;

FIG. 4 is a cross-sectional view of a chip package according to another embodiment of the present invention;

FIGS. 5A-5N are cross-sectional views of a chip packaging process according to an embodiment of the present invention; and

FIGS. 6A-6K are cross-sectional views of a chip packaging process according to another embodiment of the present invention.

### DETAILED DESCRIPTION OF THE INVENTION

The manufacturing method and method for use of the embodiment of the invention are illustrated in detail as follows. It is understood, that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numbers and/or letters in the various examples. This repetition is for the purpose of simplicity and clarity and does not in itself dictate a relationship between the various embodiments and/or configurations discussed. Furthermore, descriptions of a first layer “on,” “overlying,” (and like descriptions) a second layer, include embodiments where the first and second layers are in direct contact and those where one or more layers are interposing the first and second layers.

A chip package according to an embodiment of the present invention may be used to package a metal-oxide semiconductor field effect transistor chip, such as a power module chip. However, embodiments of the invention are not limited thereto. For example, the chip package of the embodiments of the invention may be applied to active or passive devices, or electronic components with digital or analog circuits, such as opto electronic devices, micro electro mechanical systems (MEMS), and micro fluidic systems, and physical sensors for detecting heat, light, or pressure. Particularly, a wafer scale package (WSP) process may be applied to package semiconductor chips, such as image sensor devices, light-emitting diodes (LEDs), solar cells, RF circuits, accelerators, gyroscopes, micro actuators, surface acoustic wave devices, pressure sensors, or ink printer heads.

The wafer scale packaging process mentioned above mainly means that after the packaging process is accomplished during the wafer stage, the wafer with chips is cut to obtain separate independent packages. However, in a specific embodiment, separate independent chips may be redistributed overlying a supporting wafer and then be packaged, which may also be referred to as a wafer scale packaging process. In addition, the above mentioned wafer scale packaging process may also be adapted to form chip packages of multi-layer integrated circuit devices by stacking a plurality of wafers having integrated circuits.

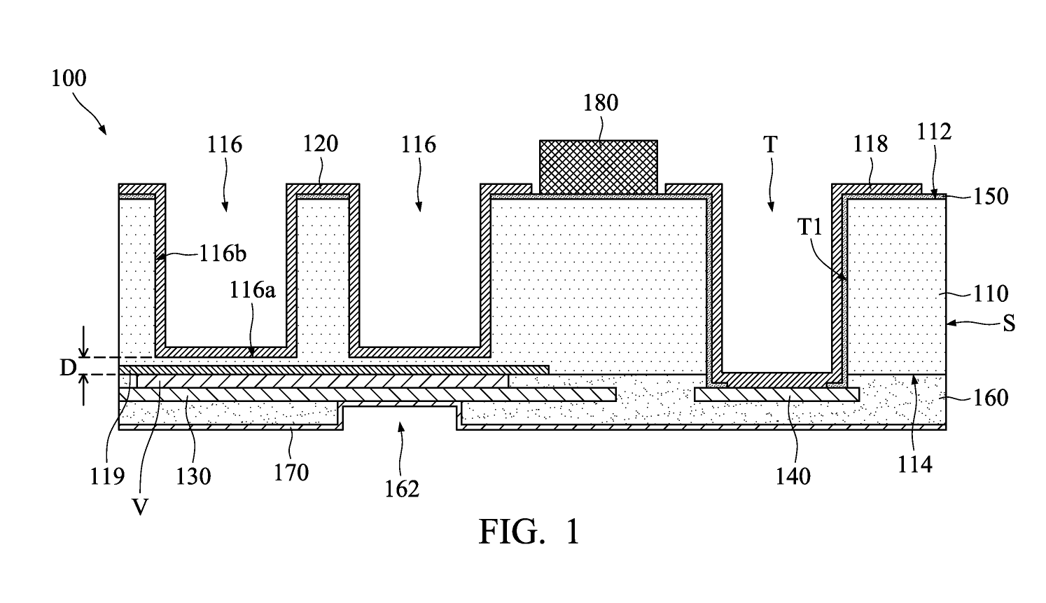

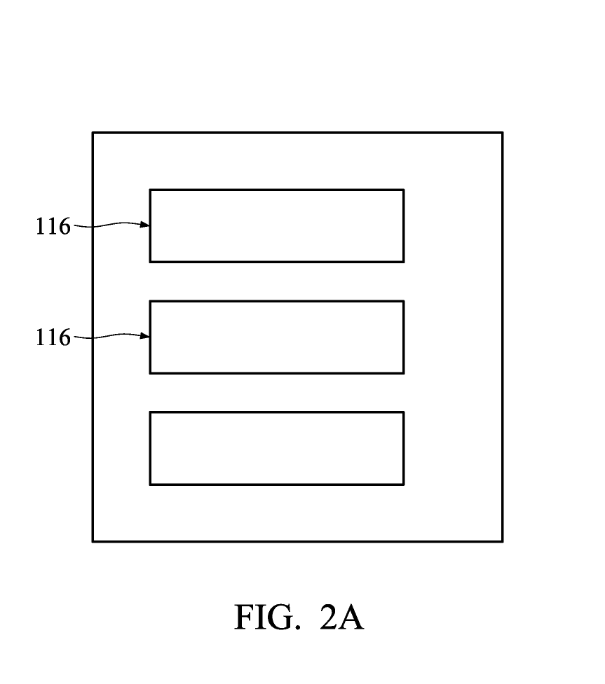

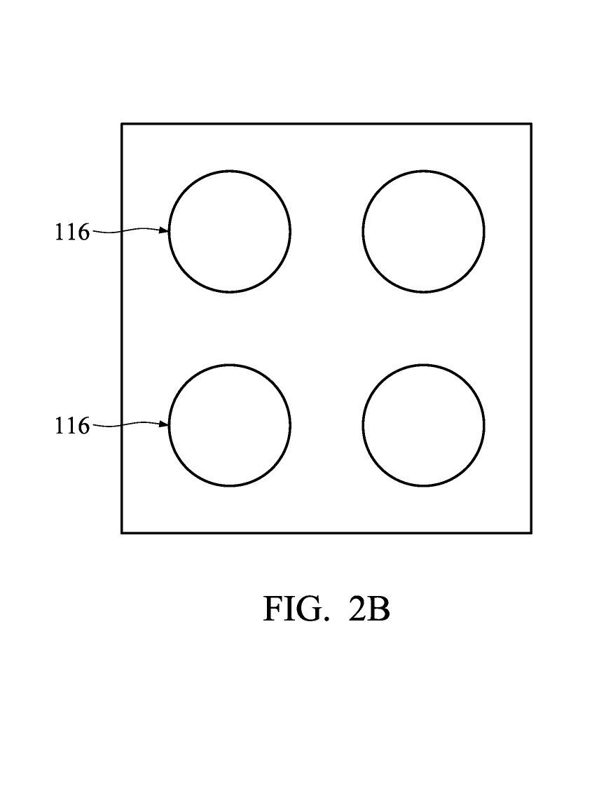

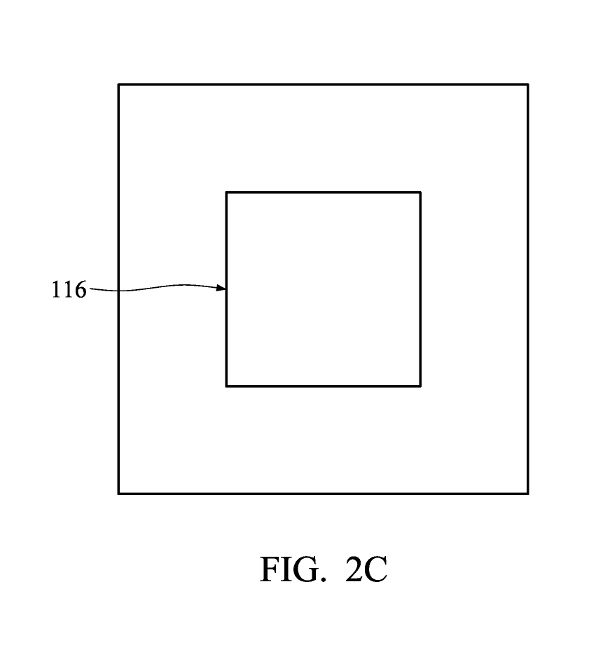

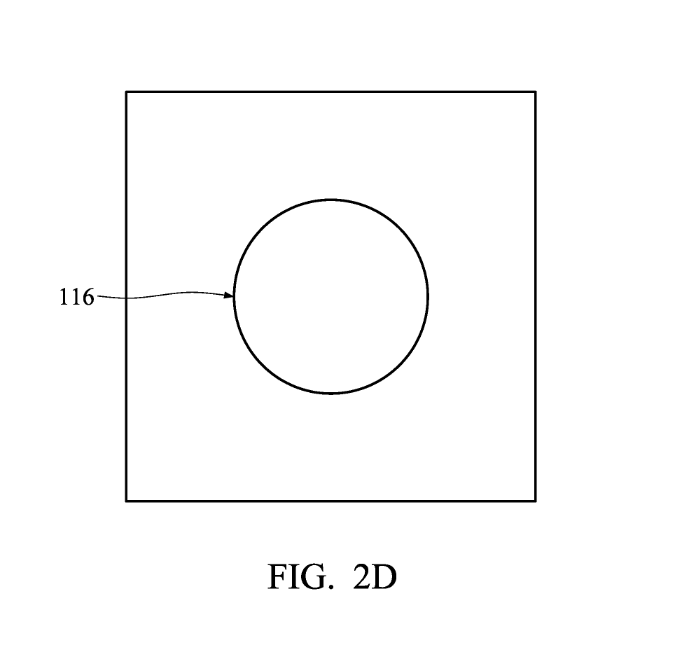

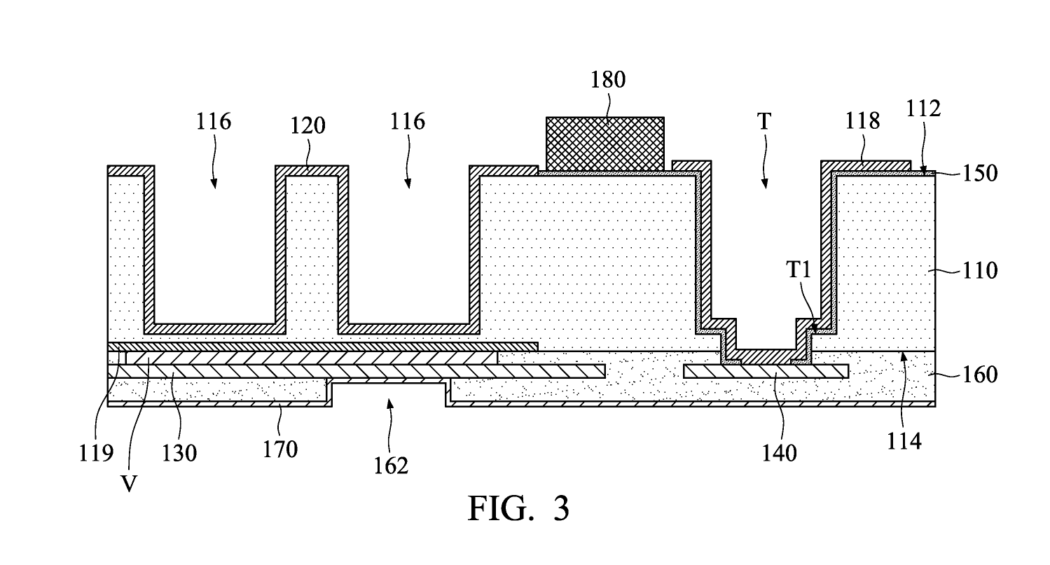

FIG. 1 is a cross-sectional view of a chip package according to an embodiment of the present invention. FIGS. 2A-2D are top views of variations of recesses of chip packages according to embodiments of the present invention. FIG. 3 is a cross-sectional view of a chip package according to an embodiment of the present invention. It should be noted that, for simplicity sake, FIGS. 2A-2D only depict shapes and arrangements of recesses and omit depicting other structures on the semiconductor substrate.

Referring to FIG. 1, a chip package 110 of the present invention includes a semiconductor substrate 110, a drain electrode 120, a source electrode 130, and a gate electrode 140, wherein the material of the semiconductor substrate 110 is, for example, silicon, germanium, silicon germanium, silicon carbide, gallium arsenide, or the like. The semiconductor substrate 110 has a first surface 112 and a second surface 114 opposite thereto.

A source region 119 and a drain region (not shown) may be pre-formed in the semiconductor substrate 110. In an embodiment, the conductive type of the semiconductor substrate 110 may be N-type or P-type. In general, N-type semiconductor substrates are mainly used. Taking an N-type semiconductor substrate 110 as an example, the semiconductor substrate 110 may be a silicon substrate doped with N-type dopants. The kinds of dopants and the doping concentration in the semiconductor substrate 110 may be nonuniform. For example, the kinds of dopants and the doping concentration of the N-type dopants doped in the portions of the semiconductor substrate 110 used as the source region 119 and the drain region respectively may be different from each other. The portion of the semiconductor substrate 110 not formed the source region 119 or other doping region (not shown) therein substantially can be a drain region. Therefore, the reference number 110 substantially can represent the drain region.

In one embodiment, the semiconductor substrate 110 may include a doping region (not shown) extending from the second surface 114 or a place close to the second surface 114 to the first surface 112. The conductive type of the doping region is different from that of the semiconductor substrate 110. For example, the conductive type of the doping region is P-type while the semiconductor substrate 110 is an N-type substrate, and vice versa.

In one embodiment, the source region 119 may be located in the doping region. The conductive type of the source region 119 is the same as that of the semiconductor substrate 110, such as N-type. In one embodiment, the source region 119 extends from the second surface 114 or a place close to the second surface 114 to the first surface 112 and is partially surrounded by the doping region. In FIG. 1A, for simplicity and clarity sake, FIG. 1A only shows the source region 119.

The first surface 112 may have at least one recess. For example, in one embodiment, the first surface 112 has a plurality of recesses 116. The recesses 116 may be in any suitable shape and arranged in any suitable way. For example, the recesses 116 as shown in FIG. 2A are in stripped shapes and arranged in a parallel way, or the recesses 116 as shown in FIG. 2B are in rounded shapes and arranged in an array. In one embodiment, the first surface 112 may have a single recess 116, and the recess 116 may be in a square shape as shown in FIG. 2C, or in a rounded shape as shown in FIG. 2D, or in other suitable shapes. In the present embodiment, a bottom 116a of the recess 116 and the second surface 114 are separated by a distance D. The distance D is, for example, about 150 micrometers to 5 micrometers, and the distance D may be shortened to 10 micrometers to 5 micrometers according to process needs or design needs.

The drain electrode 120 is disposed on the first surface 112 and covers the recess 116. In the present embodiment, the bottom 116a (and/or a sidewall 116b) of the recess 116 exposes the drain region in the semiconductor substrate 110, and the drain electrode 120 electrically connects the drain region. In the present embodiment, the drain electrode 120 directly contacts with the semiconductor substrate 110. Specifically, in the present embodiment, the drain electrode 120 covers the bottom 116a and the sidewall 116b of the recess 116 conformally. In one embodiment, the drain electrode 120 may fill the recess 116.

The source electrode 130 is disposed on the second surface 114 in a position corresponding to the recess 116, and electrically connects the source region 119 in the semiconductor substrate 110. Specifically, in the present embodiment, the source electrode 130 is disposed below the recess 116 in a position corresponding to the drain electrode 120 covering the recess 116. It should be noted that, in the present embodiment, the semiconductor substrate 110 has the recess 116, and therefore the distance between the source electrode 130 and the drain electrode 120 is shorten so as to shorten a length of a channel therebetween, thereby improving a conductive performance therebetween, and the semiconductor substrate 110 has sufficient structural strength because of the portion of the semiconductor substrate 110 outside of the recess 116.

The gate electrode 140 is disposed on the second surface 114. In the present embodiment, the chip package 100 may further include a conductive feature 118 electrically connecting the gate electrode 140 and extending onto the first surface 112.

In the present embodiment, the semiconductor substrate 110 has a through hole T in a position corresponding to the gate electrode 140, and the conductive feature 118 is located in the through hole T and connects the gate electrode 140. As shown in FIG. 1, in the present embodiment, an insulating layer 150 may be disposed between the conductive feature 118 and the semiconductor substrate 110 so as to electrically insulate the conductive feature 118 from the semiconductor substrate 110. Although the through hole T in FIG. 1 has a sidewall T1 substantially perpendicular to the second surface 114, the present invention is not limited thereto. That is, the conductive feature 118 may electrically connect the gate electrode 140 through the through hole T. In another embodiment, as shown in FIG. 3, the portion of the through hole T close to the second surface 114 has a stepwise sidewall T1. In still another embodiment, a conductive feature may connect the gate electrode 140 and be extended onto the first surface 112 along a sidewall S of the semiconductor substrate 110 (not shown). That is, the through hole T may not be formed.

It should be noted that, in the present embodiment, the conductive feature 118 extends onto the first surface 112, which enables the drain electrode 120 and the gate electrode 140 to be electrically contacted on the same surface (e.g. the first surface 112), thereby benefiting the integration with other electrical elements.

In the present embodiment, an insulating layer 160 is disposed on the second surface 114 to electrically insulate circuits and electrical devices on the second surface 114. It should be noted that the insulating layer 160 may substantially include one or a plurality of dielectric layer(s). The source electrode 130 may electrically connect to the source region 119 in the semiconductor substrate 110 through circuit layers (not shown) formed in the insulating layer 160 and/or the semiconductor substrate 110. For example, a via structure V may be formed in the insulating layer 160 and may electrically connect the source electrode 130 and the source region 119. Furthermore, in the present embodiment, the insulating layer 160 may cover the gate electrode 140 and have an opening 162 exposing the source electrode 130, and a conductive layer 170 is disposed on the insulating layer 160 and connects the source electrode 130 through the opening 162.

The insulating layers 150 and 160 is, for example, epoxy resin, solder resist layers, or other suitable insulating materials, such as inorganic materials (e.g. silicon oxide layers, silicon nitride layers, silicon oxynitride layers, metal oxide or the combination thereof); or organic polymer materials (e.g. polyimide resin, butylcyclobutene:BCB produced by Dow Chemical, parylene, polynaphthalenes, fluorocarbons, accrylates, etc.

Additionally, as shown in FIG. 1, in the present embodiment, a blocking layer 180 may be disposed on the first surface 112 and between the drain electrode 120 and the conductive feature 118 to block the solder disposed on the drain electrode 120 (or the conductive feature 118) later flow to the conductive feature 118 (or the drain electrode 120). The material of the blocking layer 180 is an insulating material, such as a solder resist material.

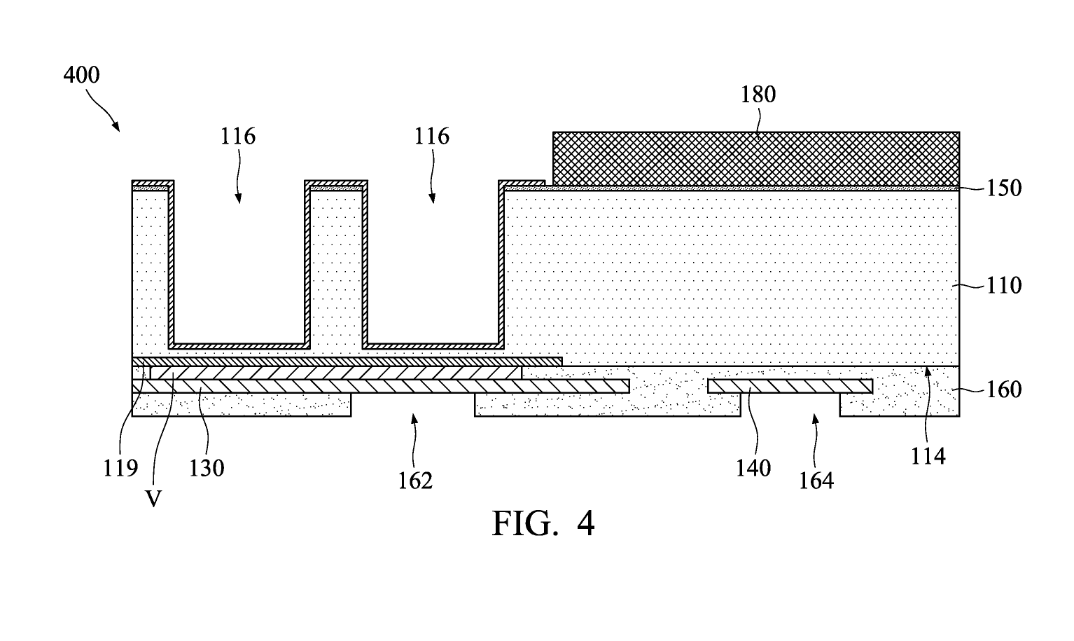

FIG. 4 is a cross-sectional view of a chip package according to another embodiment of the present invention. In an embodiment, as shown in FIG. 4, a chip package 400 may not have the conductive feature 118 depicted in the FIG. 1. Here the insulating layer 160 may further have an opening 164 exposing the gate electrode 140 for sequential electrical contacts.

A manufacturing method of the chip package as shown in FIGS. 1 and 3 will be particularly introduced as follows.

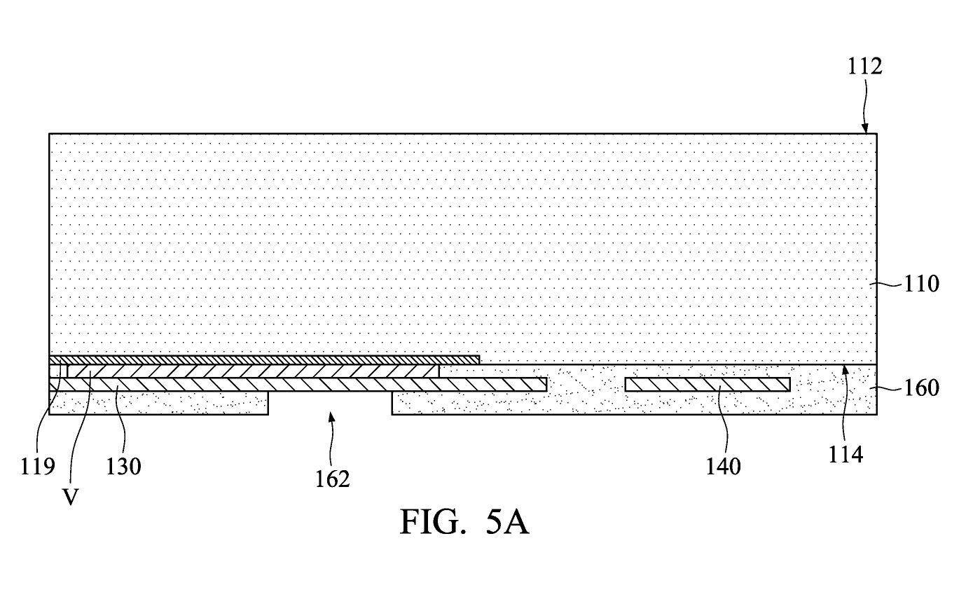

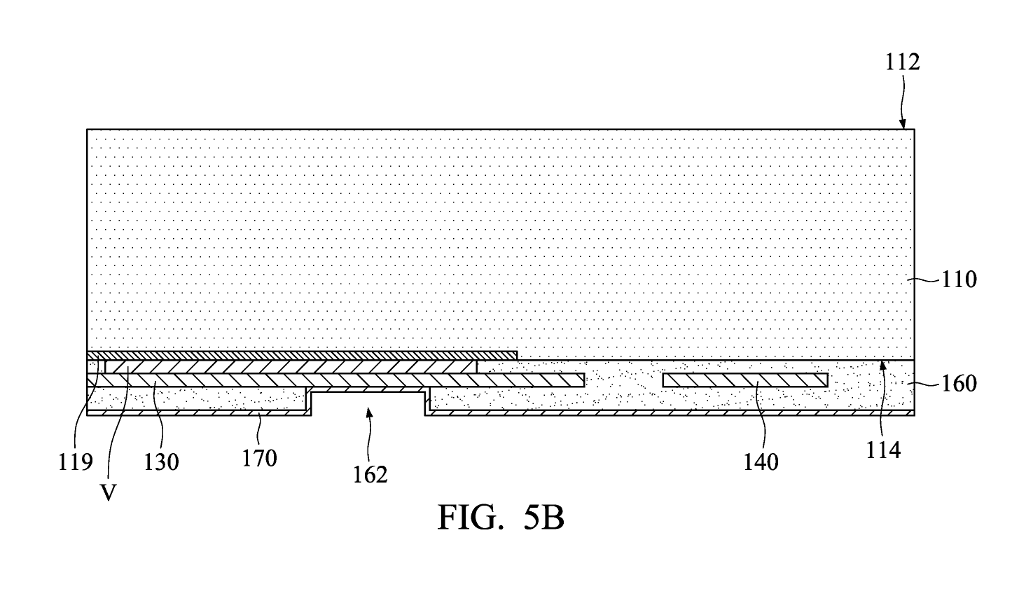

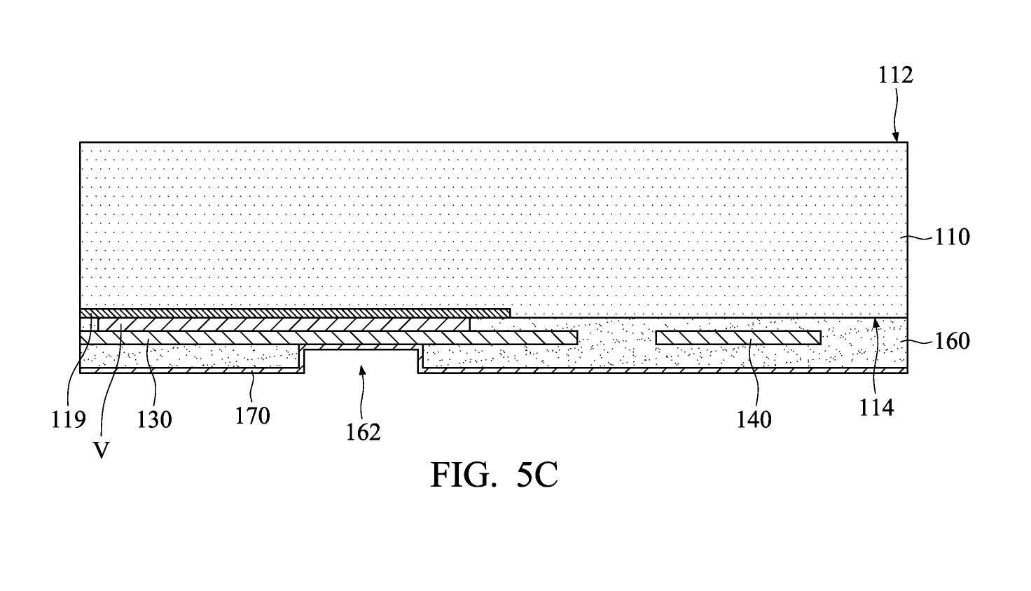

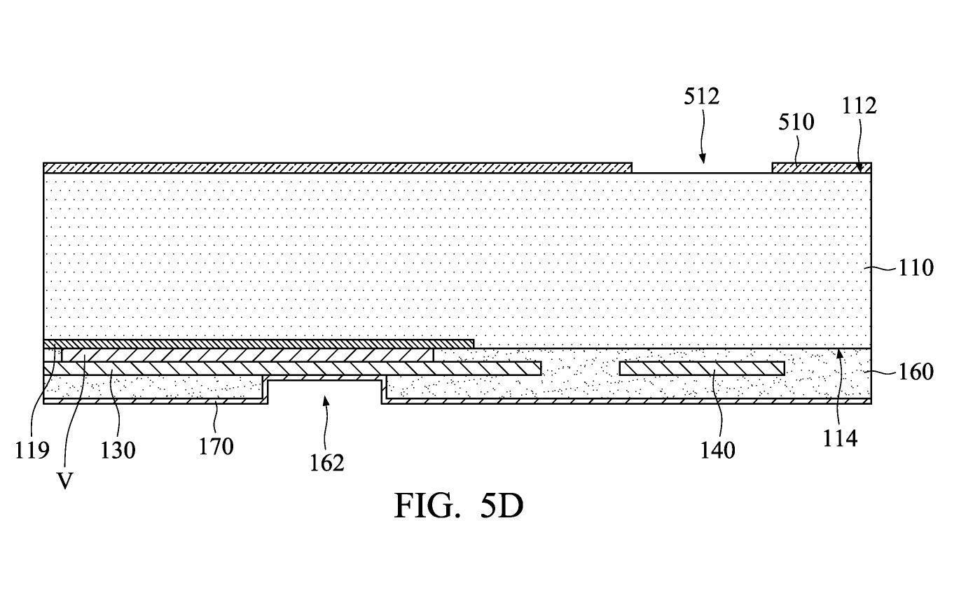

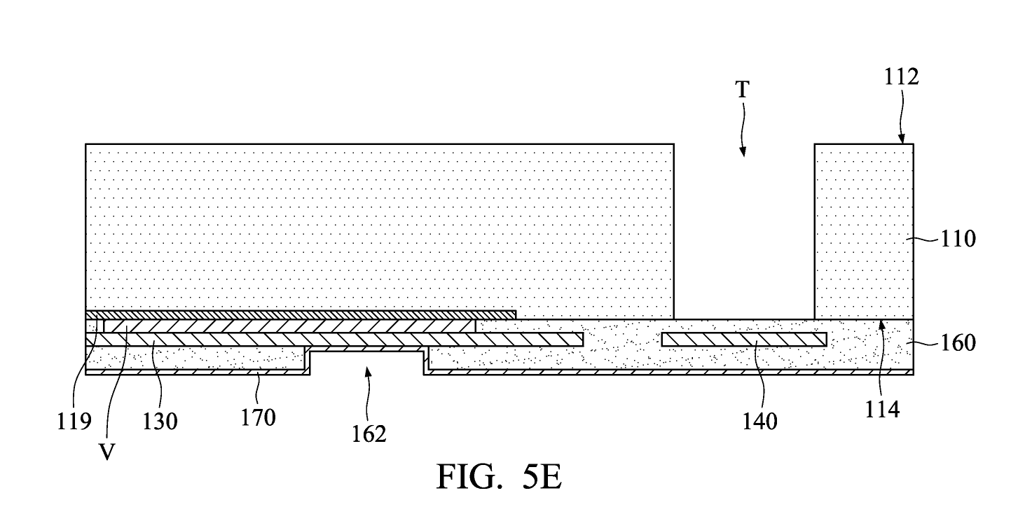

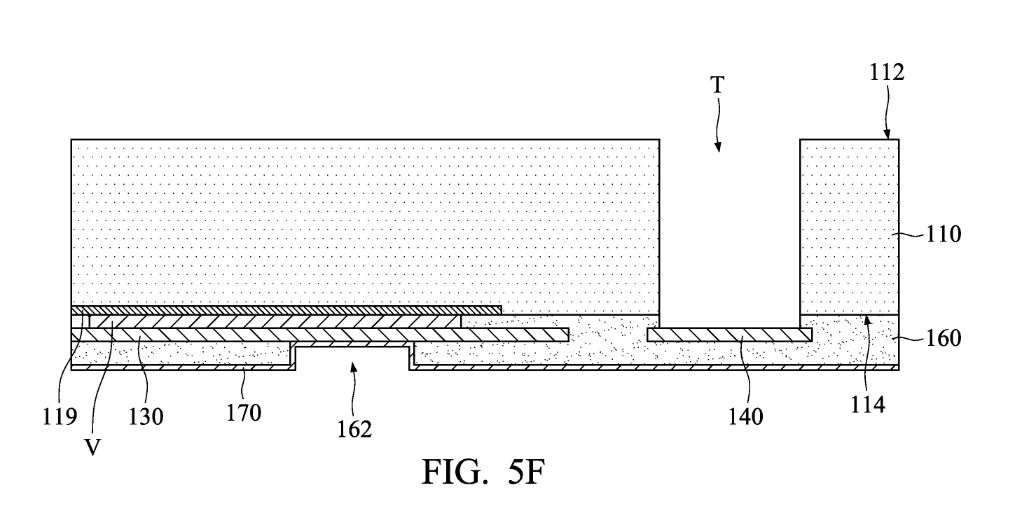

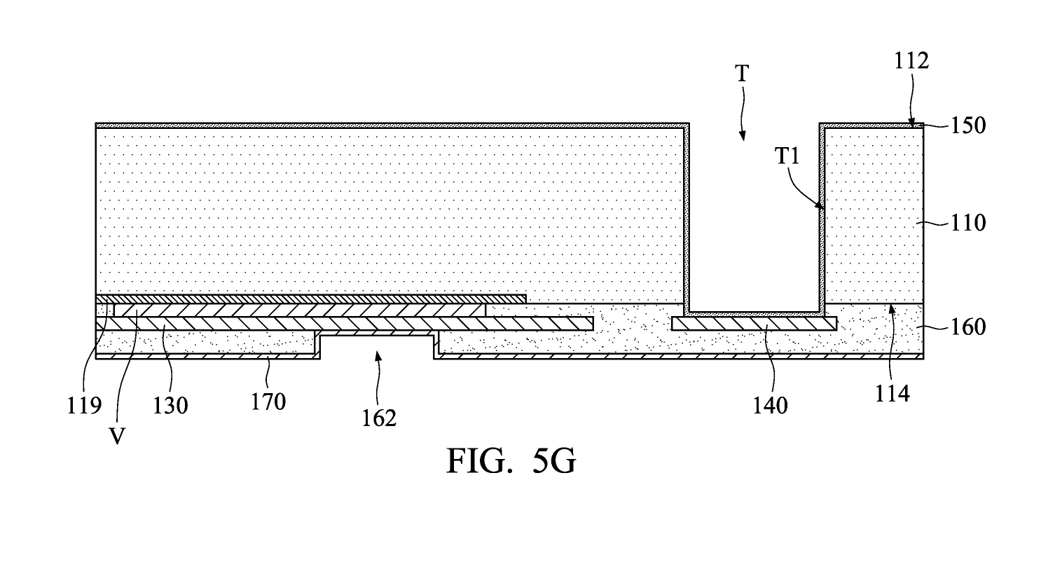

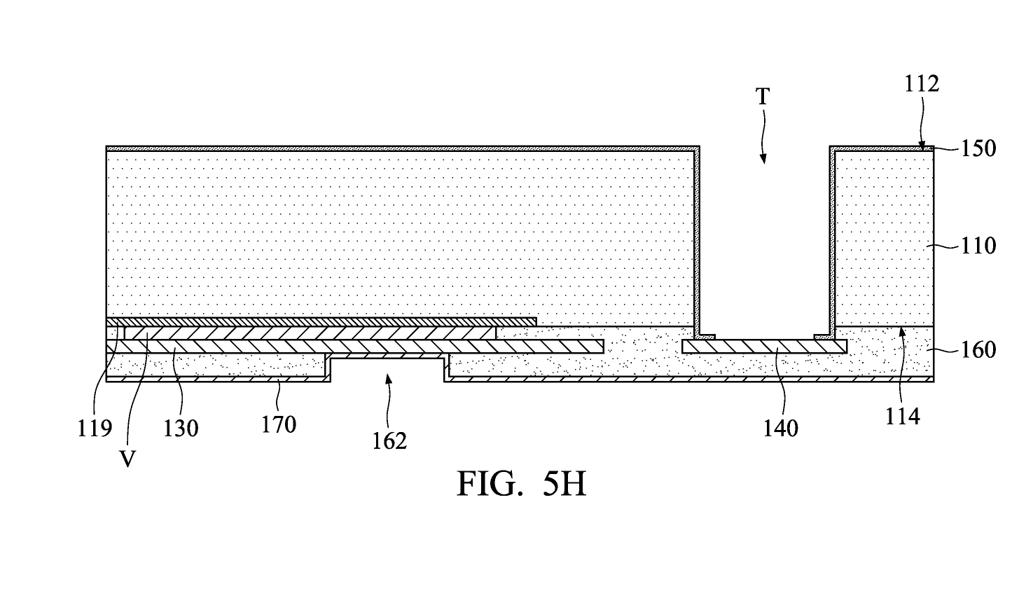

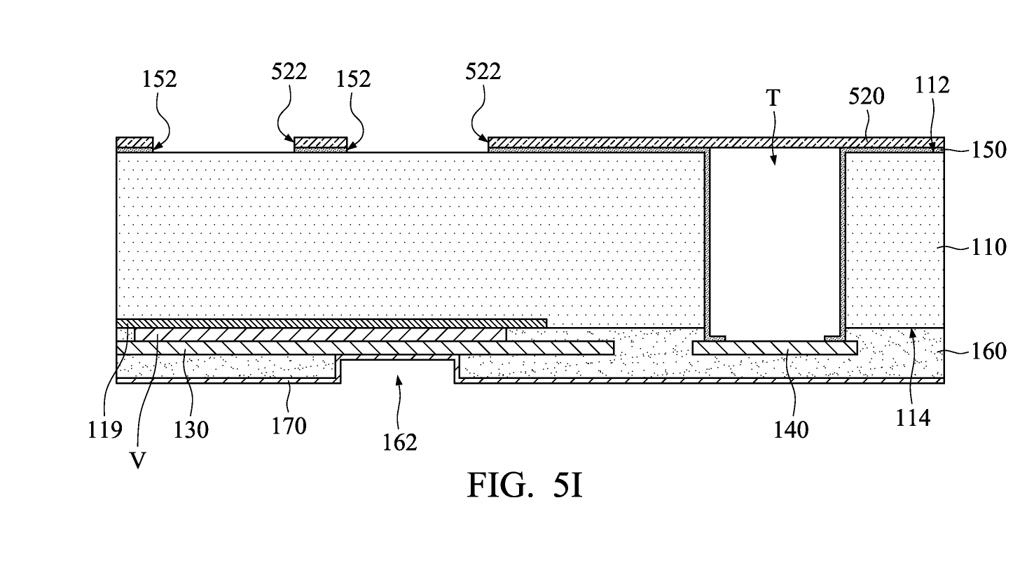

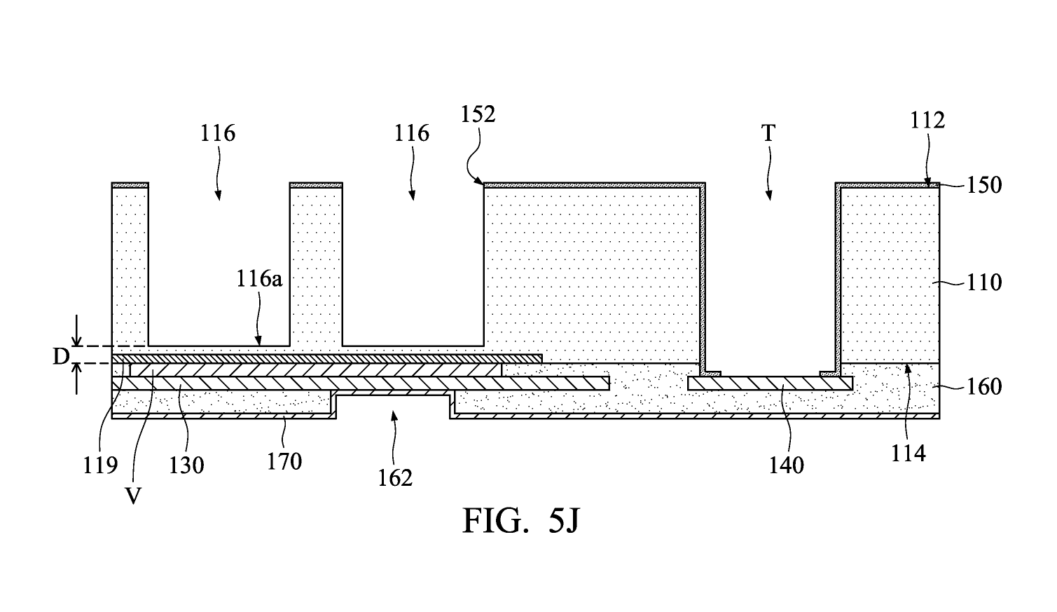

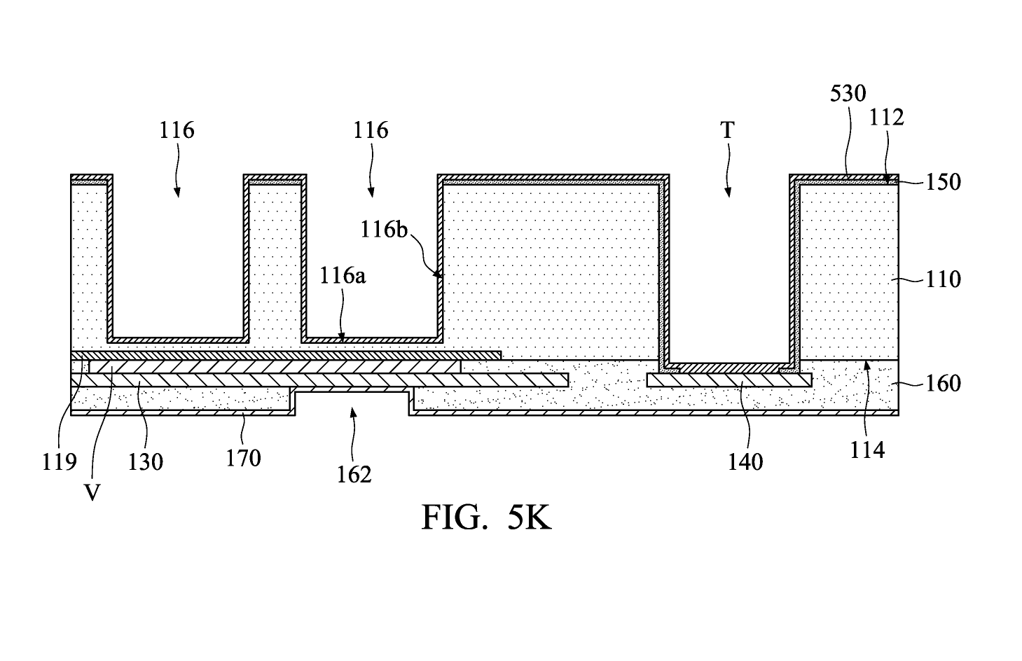

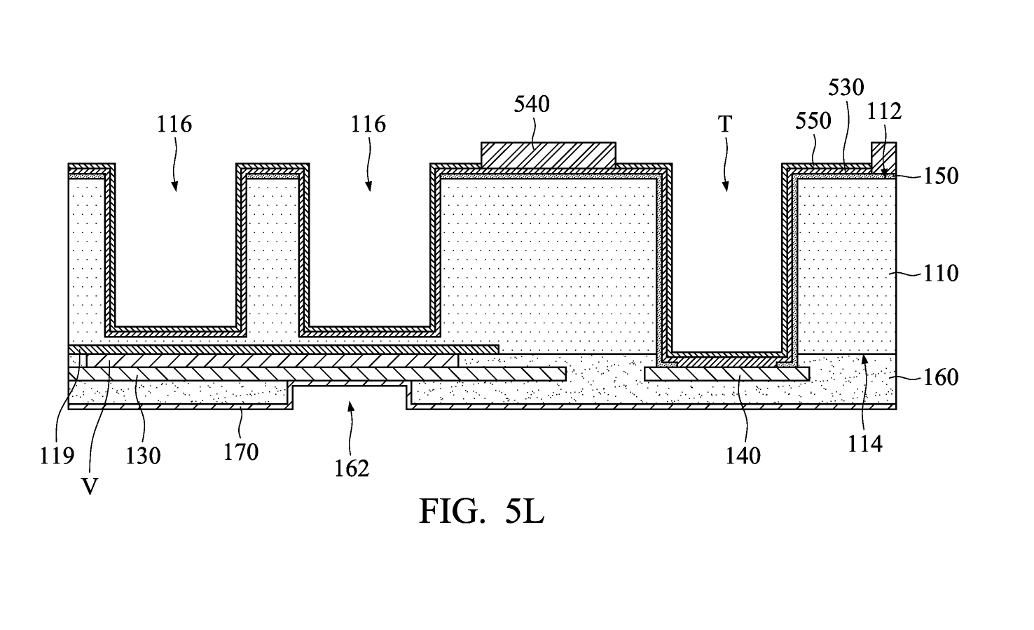

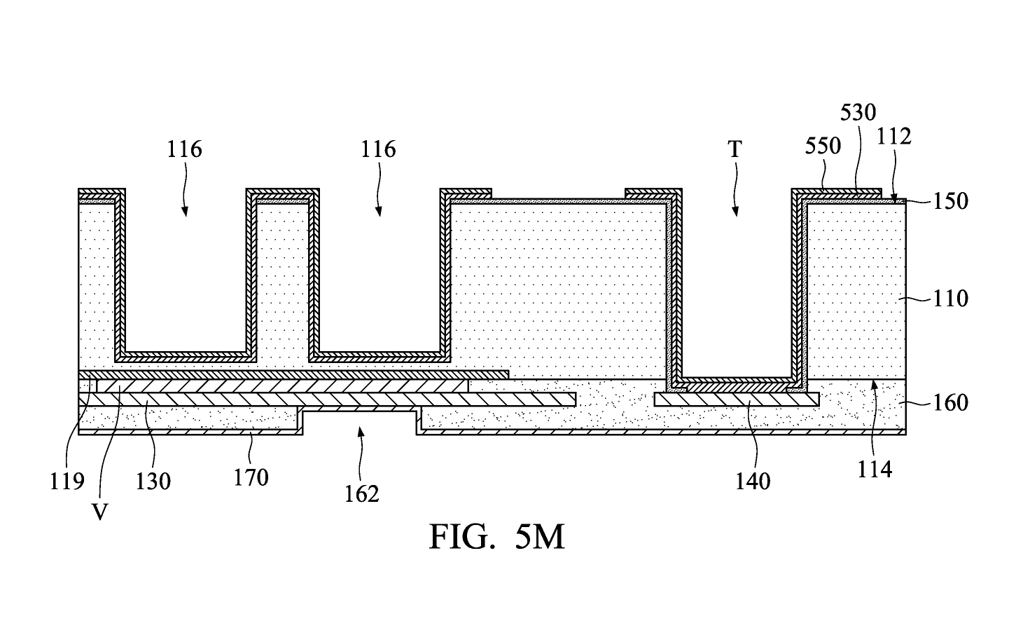

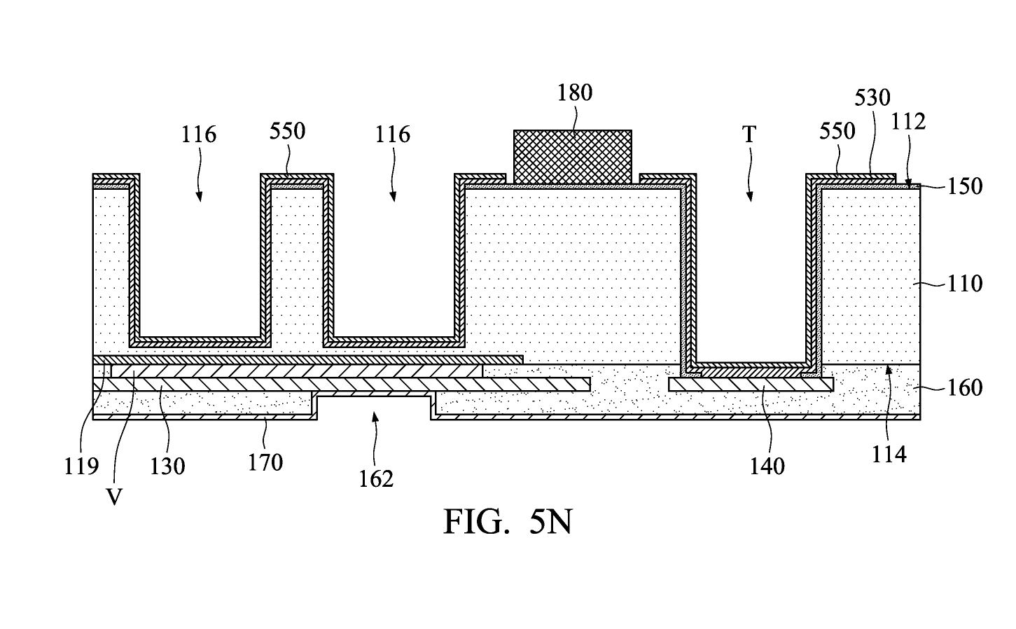

FIGS. 5A-5N are cross-sectional views of a chip packaging process according to an embodiment of the present invention. For simplicity sake, the devices which are the same as or similar to those in the FIGS. 1-4 is represented by the same reference number.

Firstly, as shown in FIG. 5A, a semiconductor substrate 110 is provided, and the semiconductor substrate 110 has a first surface 112 and a second surface 114 opposite thereto and has a source electrode 130 and a gate electrode 140 on the second surface 114. The semiconductor substrate 110 of the present embodiment is the same as the semiconductor substrate 110 in FIG. 1, and a source region 119 and a drain region (not show) are pre-formed therein.

In one embodiment, an insulating layer 160 is disposed on the second surface 114, and the source electrode 130 may electrically connect to the source region 119 in the semiconductor substrate 110 through circuit layers (not shown) formed in the insulating layer 160 and/or the semiconductor substrate 110. For example, a via structure V may be formed in the insulating layer 160 and may electrically connect the source electrode 130 and the source region 119. Furthermore, in the present embodiment, the insulating layer 160 may cover the gate electrode 140 and have an opening 162 exposing the source electrode 130.

In the present embodiment, as shown in FIG. 5B, a conductive layer 170 may be formed on the insulating layer 160 and connect the source electrode 130, through the opening 162. The conductive layer 170 is, for example, a composite layered structure formed of titanium/nickel/vanadium/silver, electroless nickel/gold, or titanium/copper/nickel/gold, or the like.

Then, as shown in FIG. 5C, the semiconductor substrate 110 may be optionally thinned. For example, the second surface 114 of the semiconductor substrate 110 is fixed on a temporary substrate (not shown), and the semiconductor substrate 110 is thinned from the first surface 112 to a suitable thickness. Then, the temporary substrate is removed. The method of thinning the semiconductor substrate 110 is, for example, etching, milling, grinding, or polishing, such as chemical mechanical polishing.

Then, as shown in FIG. 5D, a mask layer 510 may be formed on the first surface 112 and have an opening 512 exposing a portion of the semiconductor substrate 110 above the gate electrode 140. The mask layer 510 is, for example, a photoresist layer.

Then, as shown in FIG. 5E, the portion of the semiconductor substrate 110 exposed by the opening 512 is removed to form a through hole T exposing the insulating layer 160 above the gate electrode 140. The method of removing the portion of the semiconductor substrate 110 includes etching, such as dry etching, wet etching or laser etching. Then, the mask layer 510 is removed.

Then, as shown in FIG. 5F, the portion of the insulating layer 160 below the through hole T is removed, for example, by etching to expose the gate electrode 140.

Then, as shown in FIG. 5G, an insulating layer 150 is formed on the first surface 112 and the sidewall T1 of the through hole T, for example, by chemical vapor deposition or coating to insulate a conductive feature formed later from the semiconductor substrate 110. In the present embodiment, the insulating layer 150 is also formed on the gate electrode 140 exposed by the through hole T.

As shown in FIG. 5H, for the purpose that the conductive feature formed in the through hole T later can connect the gate electrode 140, the portion of the insulating layer 150 on the gate electrode 140 is removed to expose the gate electrode 140. It should be noted that the removal of the portion of the insulating layer 150 on the gate electrode 140 is not limited to occurring this step. The removal may be performed at any time before forming the conductive layer in the through hole T.

Then, as shown in FIG. 51, a mask layer 520 is formed on the first surface 112 and located on the insulating layer 150, and the mask layer 520 has a plurality of openings 522 exposing a portion of the insulating layer 150. The openings 522 are substantially above the source electrode 130. Then, by using the mask layer 520 as a mask, the portion of the insulating layer 150 exposed by the openings 522 is removed, for example, by etching to form a plurality of openings 152 in the insulating layer 150. The openings 152 expose a portion of the semiconductor substrate 110. The mask layer 520 is, for example, a dry film which will not fill into the through hole T, and accordingly a sequential through-hole cleaning process can be omitted.

Then, as shown in FIG. 5J, by using the mask layer 520 as a mask, the portion of the semiconductor substrate 110 exposed by the openings 522 is removed, for example, by etching to form a plurality of recesses 116 on the first surface 112. The recesses 116 are in a position corresponding to a source electrode 130. The recesses 116 expose the drain region (not shown) of the semiconductor substrate 110. In the present embodiment, bottoms 116a of the recesses 116 are separated from the second surface 114 by a distance D. The distance D may be modified by controlling the etching process time. Then, the mask layer 520 is removed.

Then, as shown in FIG. 5K, a seed layer 530 is formed on the first surface 112, the recesses 116 and the through hole T, and the seed layer 530 electrically connects the drain region of the semiconductor substrate 110 by connecting the bottoms 116a (and/or the sidewalls 116b) of the recesses 116. The method of forming the seed layer 530 includes chemical vapor deposition or physical vapor deposition. The seed layer 530 is, for example, a double layer structure formed of titanium/copper.

Then, as shown in FIG. 5L, an electroplating mask layer 540 is formed on the first surface 112 and between the recesses 116 and the through hole T. The electroplating mask layer 540 exposes a portion of the seed layer 530 on the recesses 116 and the through hole T. The electroplating mask layer 540 is, for example, a dry film. Then, an electroplating process is performed to form a conductive layer 550 on the seed layer 530 exposed by the electroplating mask layer 540.

Then, as shown in FIG. 5M, the electroplating mask layer 540 is removed and the seed layer 530 below the electroplating mask layer 540 is removed, for example, by etching to electrically insulate the portion of the conductive layer 550 on the recesses 116 from the portion of the conductive layer 550 on the through hole T.

It should be noted that the conductive layer in the above embodiment is formed by electroplating, but the present invention is not limited thereto. In other embodiments, the manufacturing method of the conductive layer may include vapor depositing or coating a conductive material layer; and patterning the conductive material layer by photolithography to form the needed conductive layer. Thus, the seed layer would not have to be formed in this situation.

Then, as shown in FIG. 5N, a blocking layer 180 is formed on the first surface 112 and between the portion of the conductive layer 550 on the recesses 116 and the portion of the conductive layer 550 on the through hole T. The method of forming the blocking layer 180 includes printing.

As shown in FIGS. 5A-5N, in the present embodiment, a distance between the source electrode 130 and the drain electrode (i.e. the portion of the conductive layer 550 on the recesses 116) is shortened by forming a plurality of recesses 116 in the semiconductor substrate 110, and the structural strength of the semiconductor substrate 110 is maintained by the portion outside of the recesses 116. Therefore, in the wafer process, the semiconductor substrate 110 has sufficient structural strength to avoid breakage during the transportation process and to maintain a sufficient planarity in the packaging process to avoid edge warpage caused by insufficient thickness. In one embodiment, the semiconductor substrate 110 may be a semiconductor wafer, and a plurality of metal-oxide semiconductor field effect transistors are formed therein. The metal-oxide semiconductor field effect transistors are separated from each other by predetermined scribing lines. In this situation, the semiconductor substrate 110 may further be cut along the scribing lines to form a plurality of individual chip packages for using.

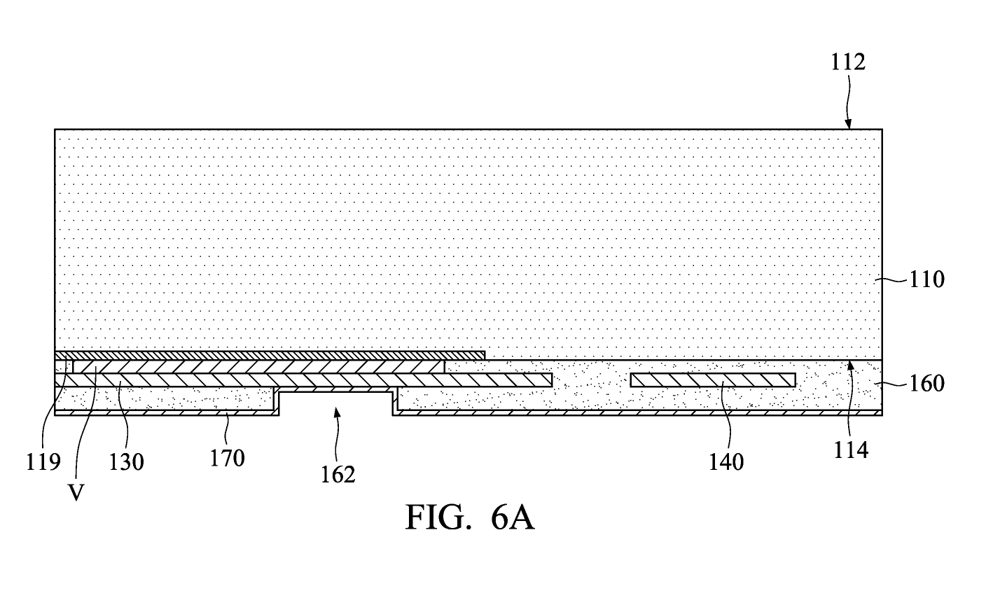

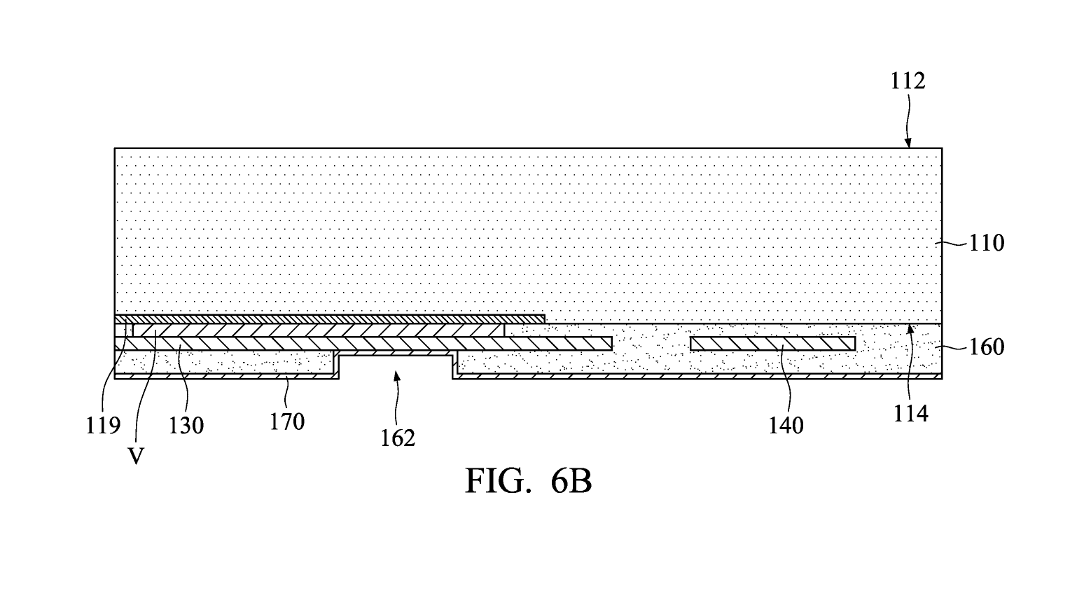

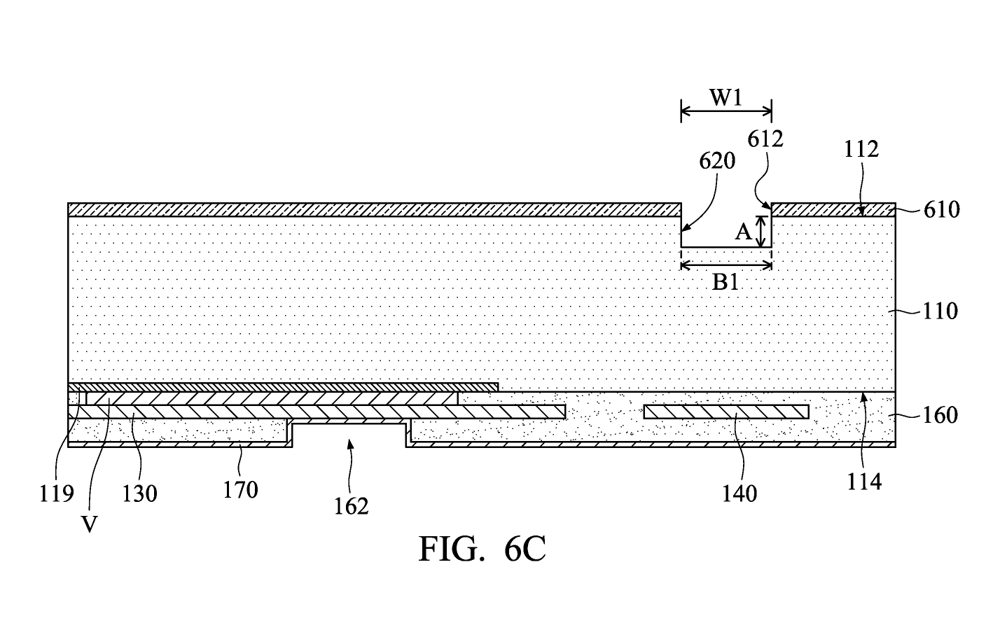

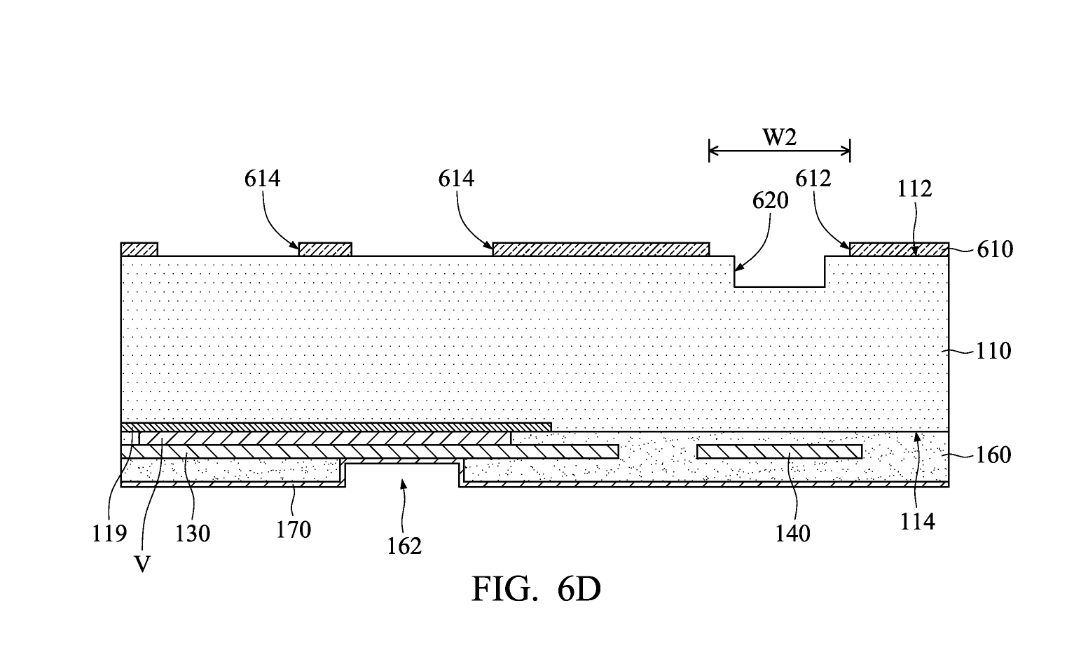

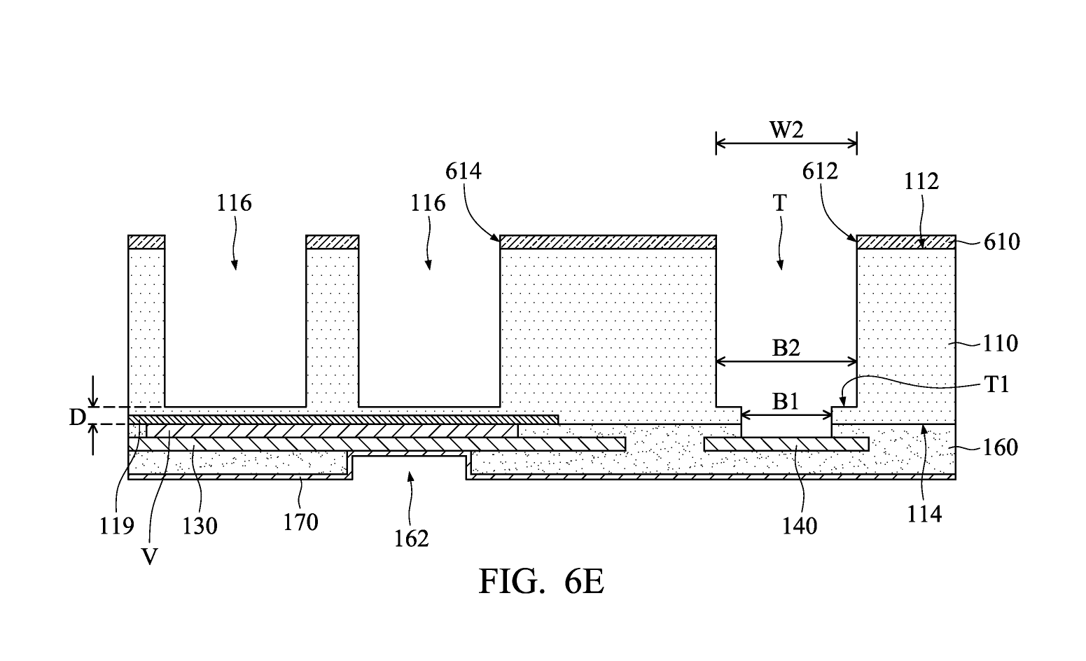

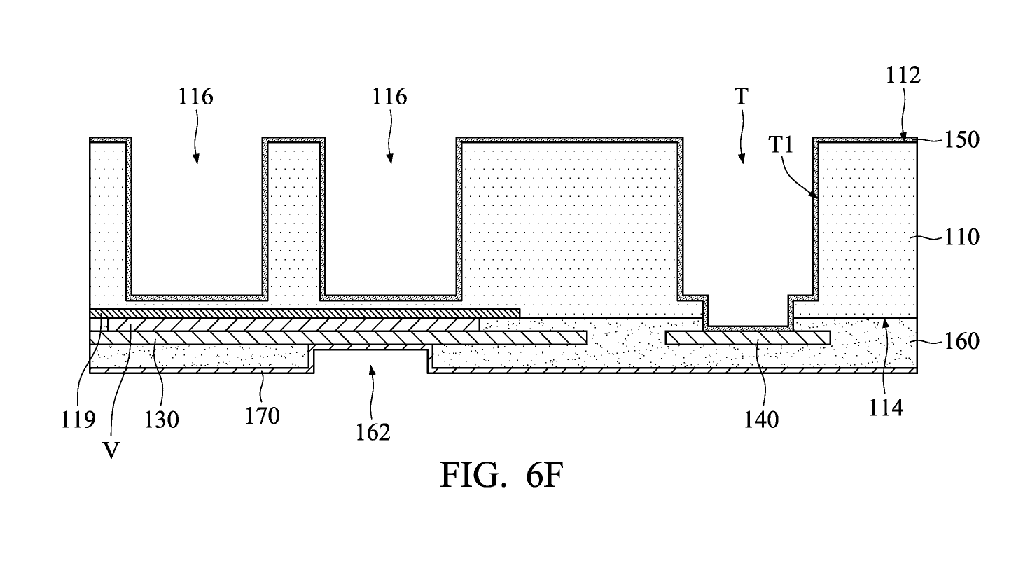

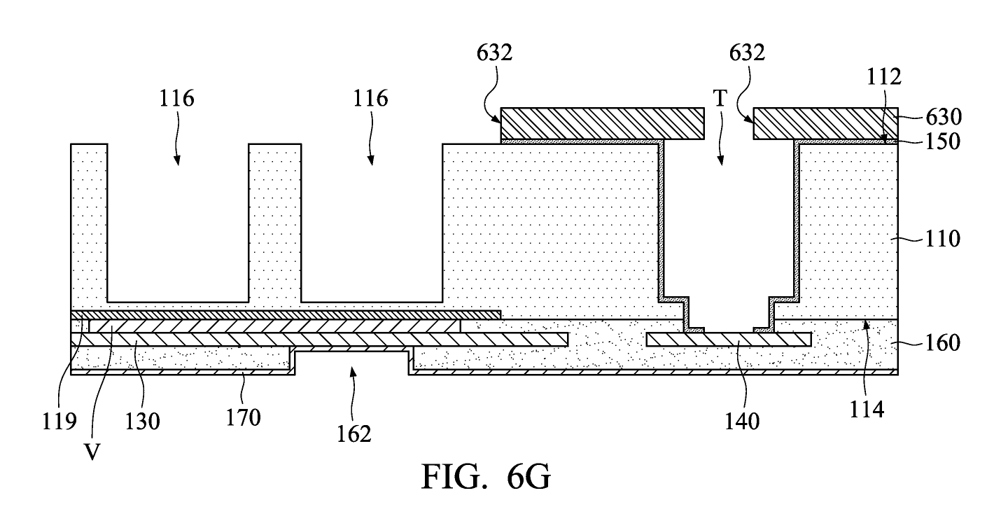

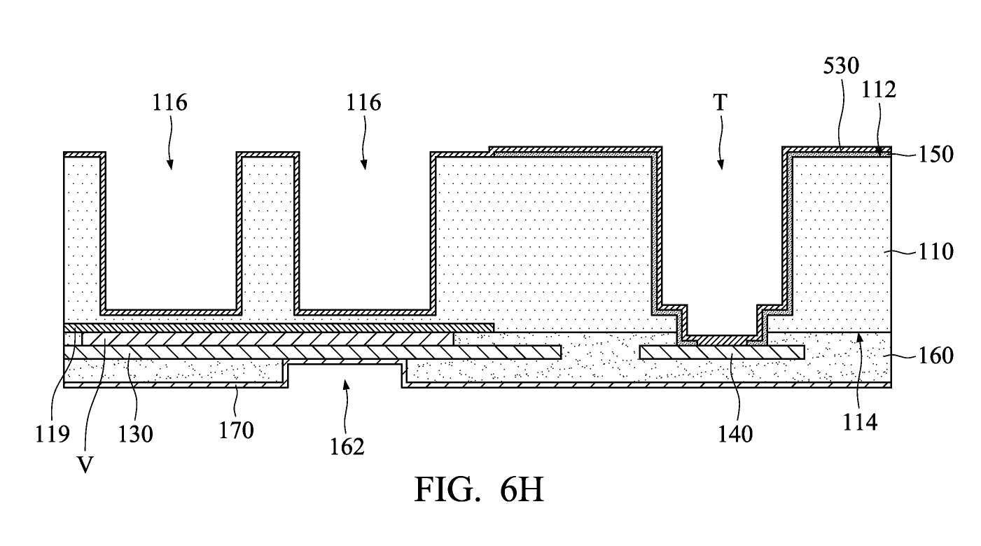

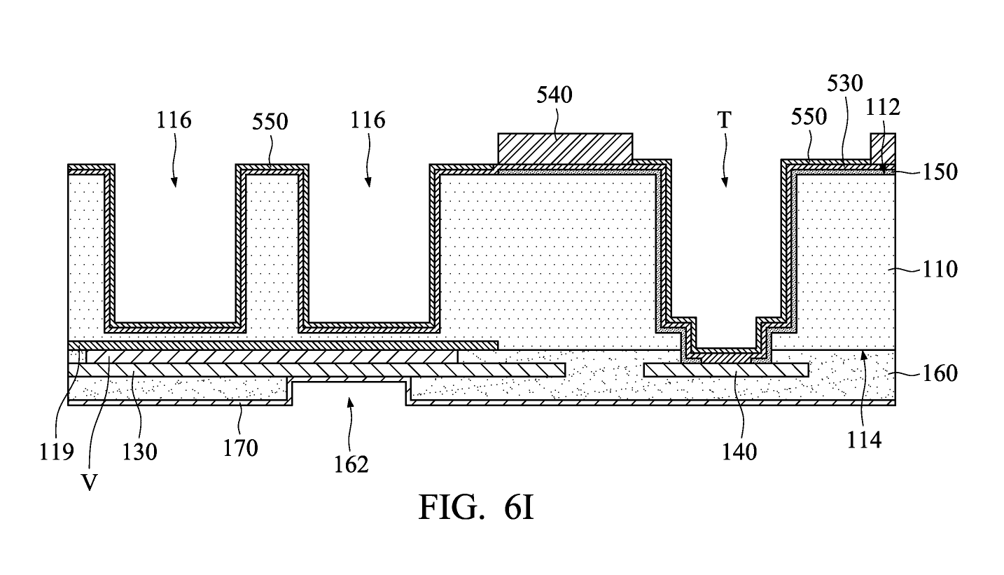

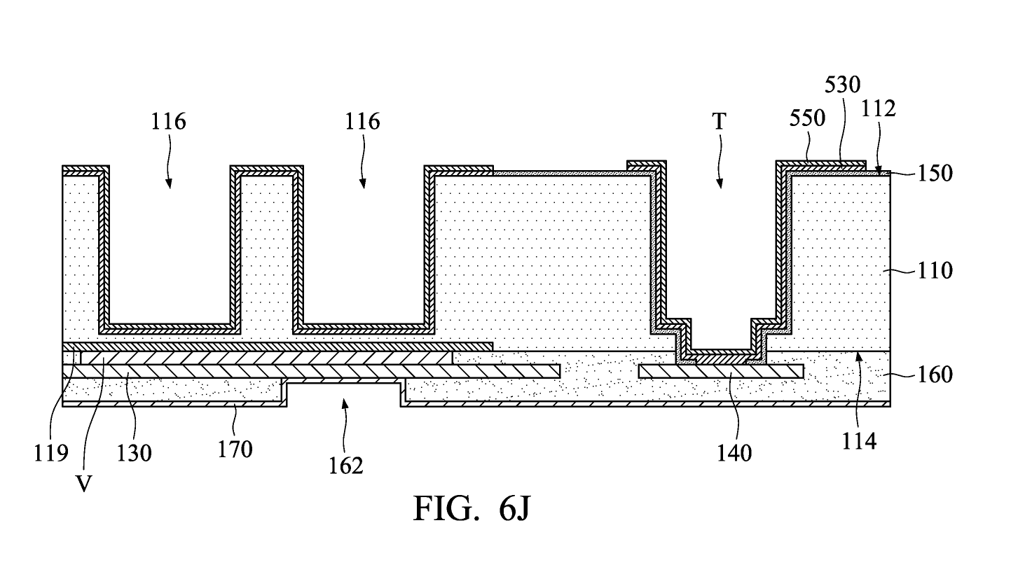

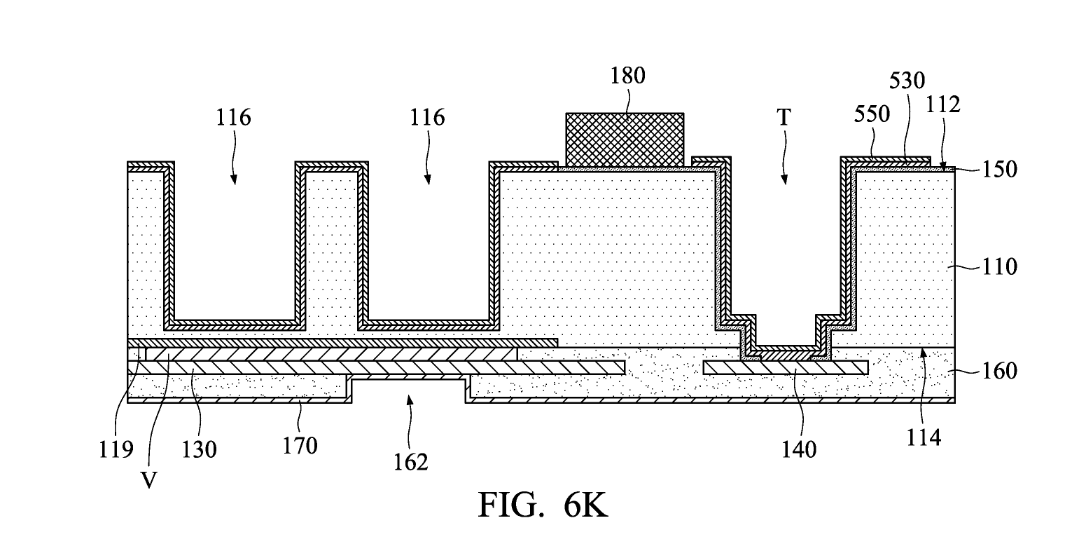

FIGS. 6A-6K are cross-sectional views of a chip packaging process according to another embodiment of the present invention. It should be noted that, in the process of FIGS. 6A-6K, the device represented by the same reference number as that in the FIGS. 1 and 5A-5N has the same material and the same manufacturing method as that in the FIGS. 1 and 5A-5N.

Firstly, as shown in FIG. 6A, a semiconductor substrate 110 is provided, and the semiconductor substrate 110 has a first surface 112 and a second surface 114 opposite thereto and has a source electrode 130 and a gate electrode 140 on the second surface 114. The semiconductor substrate 110 of the present embodiment is the same as the semiconductor substrate 110 in FIG. 1, wherein a source region 119 and a drain region (not show) are pre-formed therein.

In one embodiment, an insulating layer 160 is disposed on the second surface 114, and the source electrode 130 may electrically connect to the source region 119 in the semiconductor substrate 110 through circuit layers (not shown) formed in the insulating layer 160 and/or the semiconductor substrate 110. For example, a via structure V may be formed in the insulating layer 160 and may electrically connect the source electrode 130 and the source region 119. Furthermore, in the present embodiment, the insulating layer 160 may cover the gate electrode 140 and have an opening 162 exposing the source electrode 130. Then, a conductive layer 170 may be formed on the insulating layer 160 and connect the source electrode 130 through the opening 162.

Then, as shown in FIG. 6B, the semiconductor substrate 110 may be thinned optionally. For example, the second surface 114 of the semiconductor substrate 110 is fixed on a temporary substrate (not shown), and the semiconductor substrate 110 is thinned from the first surface 112 to a suitable thickness. Then, the temporary substrate is removed.

Then, as shown in FIG. 6C, a mask layer 610 may be formed on the first surface 112 and have an first opening 612 exposing a portion of the semiconductor substrate 110 above the gate electrode 140. The first opening 612 has a width W1. Then, the portion of the semiconductor substrate 110 exposed by the first opening 612 is removed by using the mask layer 610 as a mask to form a recess 620. A depth A of the recess 620 is, for example, 25 micrometers to 50 micrometers. A width B1 of the recess 620 is, for example, about equal to the width W1 of the first opening 612.

Then, as shown in FIG. 6D, the mask layer 610 is patterned to form a plurality of second openings 614 and enlarge the first opening 612 such that the first opening 612 has a width W2 larger than the width W1. The second openings 614 expose a portion of the semiconductor substrate 110 above the source electrode 130.

Then, as shown in FIG. 6E, by using the mask layer 610 as a mask, a portion of the semiconductor substrate 110 exposed by the second openings 614 and the first opening 612 is removed, for example, by etching so as to form recesses 116 and a through hole T at the same time. The through hole T exposes the gate electrode 140, and the recesses 116 are substantially above the source electrode 130.

It should be noted that because the recess 620 has been pre-formed below the first opening 612, in this step a through hole T penetrating through the semiconductor substrate 110 is formed under the first opening 612, and the recesses 116 formed below the second openings 614 are separated from the second surface 114 by a distance D. In brief, in the present embodiment, a shallower recess 620 is formed in the semiconductor substrate 110 above the gate electrode 140, and then the portion of the semiconductor substrate 110 under the recess 620 is removed in the process of forming the recesses 116 to form the through hole T. As such, the more difficult through hole process is replaced by the easier recess process.

Additionally, a width B2 of the through hole T is, for example, about equal to the width W2 of the first opening 612. Because the width W2 is larger than the width W1, the width B2 is larger than the width B1. Therefore, the portion of the through hole T close to the second surface 114 has a stepwise sidewall T1.

Then, as shown in FIG. 6F, the mask layer 610 is removed. Then, an insulating layer 150 is formed on the inner wall T1 of the through hole T and the first surface 112. In the present embodiment, the insulating layer 150 is also formed on the gate electrode 140 exposed by the through hole T and the recesses 116. Therefore, the process as shown in FIG. 6G may be performed. A mask layer 630 (e.g. a dry film) is formed on the first surface 112, and the mask layer 630 is on the insulating layer 150 and has a plurality of openings 632 exposing the portion of the insulating layer 150 on the recesses 116 and the gate electrode 140, and then the portion of the insulating layer 150 exposed by the mask layer 630 is removed by using the mask layer 630 as a mask.

Then, as shown in FIG. 6H, the mask layer 630 is removed, and then a seed layer 530 is formed on the first surface 112, the recesses 116 and the through hole T.

Then, as shown in FIG. 61, an electroplating mask layer 540 is formed on the seed layer 530 and between the recesses 116 and the through hole T. Then, an electroplating process is performed to form a conductive layer 550 on the seed layer 530 exposed by the electroplating mask layer 540.

Then, as shown in FIG. 6J, the electroplating mask layer 540 is removed and the seed layer 530 below the electroplating mask layer 540 is removed to electrically insulate the portion of the conductive layer 550 on the recesses 116 from the portion of the conductive layer 550 on the through hole T.

Then, as shown in FIG. 6K, a blocking layer 180 is formed on the first surface 112 and between the portion of the conductive layer 550 on the recesses 116 and the portion of the conductive layer 550 on the through hole T.

In the embodiments of the present invention, the formation of the recess in the semiconductor substrate shorten the distance between the source electrode and the drain electrode so as to shorten a length of a channel therebetween, thereby improving a conductive performance therebetween, and the semiconductor substrate has sufficient structural strength because of the portion of the semiconductor substrate outside the recess. In the wafer process, the semiconductor substrate has sufficient structural strength to avoid breakage during a transportation process and to maintain sufficient planarity in the packaging process to avoid edge warpage caused by a too small? thickness.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A chip package, comprising:
a semiconductor substrate having a first surface and a second surface opposite thereto, wherein the first surface has a recess;
a drain electrode disposed on the first surface and covering the recess;
a source electrode disposed on the second surface in a position corresponding to the drain electrode covering the recess; and
a gate electrode disposed on the second surface.

2. The chip package as claimed in claim 1, further comprising:
a conductive feature electrically connecting the gate electrode and extending onto the first surface.

3. The chip package as claimed in claim 2, wherein the semiconductor substrate has a through hole corresponding to the gate electrode, and the conductive feature is in the through hole and connects the gate electrode.

4. The chip package as claimed in claim 3, wherein a portion of the through hole neighboring the second surface has a stepwise sidewall.

5. The chip package as claimed in claim 2, further comprising:
an insulating layer disposed on the second surface and covering the gate electrode, wherein the insulating layer has an opening exposing the source electrode; and
a conductive layer disposed on the insulating layer and connecting the source electrode, through the opening,.

6. The chip package as claimed in claim 2, further comprising:
a blocking layer disposed on the first surface and between the drain electrode and the conductive feature.

7. The chip package as claimed in claim 2, further comprising:
an insulating layer disposed between the conductive feature and the semiconductor substrate to electrically insulate the conductive feature from the semiconductor substrate.

8. The chip package as claimed in claim 1, wherein the first surface has a plurality of recesses covered by the drain electrode.

9. The chip package as claimed in claim 1, wherein the drain electrode conformally covers a bottom and a sidewall of the recess.

10. The chip package as claimed in claim 1, wherein a distance between a bottom of the recess and the second surface is about 150 micrometers to 5 micrometers.

11. A chip package, comprising:
a semiconductor substrate having a first surface and a second surface opposite thereto, and having at least one recess extending from the first surface to the second surface, wherein the recess has a bottom;
a drain electrode disposed on the first surface and covering the recess;
a source electrode disposed on the second surface in a position corresponding to the drain electrode covering the recess;
a gate electrode disposed on the second surface;
a conductive feature electrically connecting the gate electrode, penetrating through the semiconductor substrate, and extending onto the first surface;
an insulating layer disposed on the second surface and covering the gate electrode, wherein the insulating layer has an opening exposing the source electrode; and
a conductive layer disposed on the insulating layer and connecting the source electrode, through the opening.

12. A method for forming a chip package, comprising:
providing a semiconductor substrate, a source electrode and a gate electrode, wherein the semiconductor substrate has a first surface and a second surface opposite thereto, and the source electrode and the gate electrode are located on the second surface;
forming a first recess on the first surface, wherein the first recess is in a position corresponding to the source electrode; and
forming a drain electrode on the first surface, covering the first recess.

13. The method for forming a chip package as claimed in claim 12, further comprising:
forming a through hole in the semiconductor substrate and in a position corresponding to the gate electrode; and
forming a conductive feature in the through hole, wherein the conductive feature connects the gate electrode and extends onto the first surface.

14. The method for forming a chip package as claimed in claim 13, further comprising:
before forming the conductive feature, forming an insulating layer on the first surface and an inner wall of the through hole to electrically insulate the conductive feature from the semiconductor substrate.

15. The method for forming a chip package as claimed in claim 13, wherein the drain electrode and the conductive feature are formed during the same step.

16. The method for forming a chip package as claimed in claim 15, wherein the forming of the drain electrode and the conductive feature comprises:
after forming the first recess and the through hole, forming an electroplating mask layer on the first surface and between the first recess and the through hole;
performing an electroplating process to form the drain electrode and the conductive feature on the first recess, the through hole and the first surface exposed by the electroplating mask layer; and
removing the electroplating mask layer.

17. The method for forming a chip package as claimed in claim 13, further comprising:
after forming the conductive feature, forming a blocking layer on the first surface and between the drain electrode and the conductive feature.

18. The method for forming a chip package as claimed in claim 13, wherein the forming of the through hole comprises:
forming a second recess on the first surface, wherein the second recess is above the gate electrode; and
removing a portion of the semiconductor substrate under the second recess while forming the first recess.

19. The method for forming a chip package as claimed in claim 18, wherein the forming of the through hole comprises:
forming a mask layer on the first surface, wherein the mask layer has a first opening exposing a portion of the semiconductor substrate;
removing the semiconductor substrate exposed by the first opening by using the mask layer as a mask to form the second recess;
patterning the mask layer to form at least a second opening and to enlarge a width of the first opening;
removing the semiconductor substrate exposed by the second opening and the first opening by using the mask layer as a mask to form the first recess and the through hole; and
removing the mask layer.

20. The method for forming a chip package as claimed in claim 13, further comprising:
forming an insulating layer on the second surface, wherein the insulating layer covers the gate electrode and has an opening exposing the source electrode; and
forming a conductive layer on the insulating layer, wherein the conductive layer connects the source electrode through the opening.
